(19) United States
(12) Patent Application Publication
(10) Pub. No.: US 2002/0160111 A1
(43) Pub. Date: Oct. 31, 2002

(54) Method for fabrication of field emission devices using carbon nanotube film as a cathode

(76) Inventors: Yi Sun, Woodside, NY (US); Zhuo Sun, Woodside, NY (US)

Correspondence Address: Yunling Ren, Esq., Cohen, Pontani, Lieberman & Pavane, 551 Fifth Avenue, Suite 1210, New York, NY, 10176, US

(21) Appl. No.: 10/127,296

(22) Filed: Apr. 22, 2002

Related U.S. Application Data
(60) Provisional application No. 60/285,977, filed on Apr. 25, 2001.

(51) Int. Cl. B05D 3/02; C23C 16/00

(52) U.S. Cl. 427/248.1; 427/376.1; 118/723 MP

(57) ABSTRACT

The present invention relates to field emission deices fabrication using carbon nanotube film as a cathode. The multi-wall carbon nanotubes film possesses low electron field emission and high emission current density, which is deposited by catalytic chemical vapor deposition at low temperature. The carbon nanotubes density can be controlled by tuning of the transition metal catalysts in the seed alloy layer. The film can be deposited onto the substrate uniformly with large area. The present invention is related to the fabrication of cold electron sources, florescent light, vacuum electronic devices, field emission displays and methods of making same.

### RELATED APPLICATIONS

This application claims priority from U.S. Provisional Patent Application Serial No. 60/285,977 which was filed on Apr. 25, 2001.

### BACKGROUND OF THE INVENTION

1. Field of the Invention

The present invention relates to nanometer sized carbon tubes film deposition and related field emission devices fabrication. The multi-wall carbon nanotube film possessed excellent field emission properties is deposited by catalytic chemical vapor deposition at low temperature over large area. The present invention is related to fabrication of cold electron sources, florescent light, vacuum electronic devices, field emission displays using the carbon nanotube film as electron cathode and methods of making same.

2. Description of the Related Art

Various field emission cathodes have been proposed for flat panel displays and vacuum microelectronics applications. Cold cathode possesses very low power dissipation, comparing with the hot-electron cathode. Field emission devices are promising in the potential applications in flat panel display, vacuum microelectronics, and some special lighting. An important application is field emission display. The advantages of such display device include: high resolution; high luminous efficiency, very thin and light, wide operating temperature range, high contrast and crisp images, wide viewing angle, low consume power, fast response time. The field emission displays are solid-state vacuum displays that operate similarly to cathode ray tubes. They are based on cold emission of electrons from a matrix array of metal or semiconductor microtips or film emitters. Microtips are small, sharp cones with sharp tips that serve as cathodes, the typical size of the cone is one micron or below. However, the fabrication process of microtips is complicated and costly, in part because the high-resolution photolithography process is required. Another alternatives being explored is the cathode using carbon-based thin films, such as diamond, diamond-like carbon and carbon nanotubes films as the emitters. The structure of devices and fabrication process for these carbon-based emitters is much simple. However, the poor conductivity of diamond and diamond like carbon films limits the emission current density for practical application. Among these, carbon nanotube is a good material for electron field emission application because of its excellent field emission properties, such as low electron emission threshold field and high emission current density. Further, carbon nanotubes possess good electron conductivity and the emission local field enhancement is high due to the high aspect ratios.

The carbon nanotubes consist of cylindrical arrangements of carbon atoms. Depending on single layer or multi-layers of the tube wall, carbon nanotubes can be termed either single-walled or multi-walled carbon nanotubes. The conventional synthesis method for carbon nanotube is carbon arc discharge. However, the carbon nanotubes synthesized by arc-discharge normally mixed with many nano graphite particles which are difficult to be separated from the carbon nanotubes. On the other hand, the growth of thin film through this process is very difficult. Conventionally, a thin film of carbon nanotube can be prepared by pyrolysis of hydrocarbon precursor using metal catalysts at high temperature (above 800° C.). However, the growth temperature is high and cannot be applied to some common substrate such as glass yet it is important for practical application of field emission devices, especially for flat panel display. In addition, for vacuum-electronic devices application, growth of patterned carbon nanotubes array as a cold cathode is important for high current density emission.

In this invention, the fabrication process carbon nanotubes film arrays at low temperature and related field emission devices are introduced. The carbon nanotubes film has been used as a cold cathode which possesses good electron field emission properties, lower threshold field, high emission current density. The process is simple for field emission device fabrication.

The object of the present invention to provide a low temperature growth of uniform carbon nanotubes thin films over large area by catalytic chemical vapor deposition.

It is another object of the present invention to provide carbon nanotubes arrays as cathodes for field emission devices application.

It is another object of the present invention to provide a process for controlling carbon nanotubes density by using transition metal alloy, compound or composite as a seed layer.

It is another object of the present invention to provide a process for fabrication of diode-type and triode-type field emission devices using carbon nanotubes film arrays as cathodes.

It is another object of the present invention to provide a process for fabrication of field emission display devices which exhibit uniform and high density of luminescent spots on anode at low field using carbon nanotubes film arrays as cathodes.

Other objects and advantages will become apparent from the following disclosure.

### SUMMARY OF THE INVENTION

The present invention field emission devices include fabrication of carbon nanotubes films by catalytic chemical vapor deposition (CVD) using transit metal catalysts thin film, such as Ni, Pd, Pt, Fe, Ru, Os, Co, Rh, Ir, Cu, Ag, Au, Zn, Cd, Mn, Tc, Re, Cr, Mo, W, V, Nb, Ta, Ti, Zr Hf, Sc, Y, La, and related alloys, compounds or composite films, such as Ni/Fe, Ni/Co, Ni/Cr, Ni/Ti, Ni/W, Ni/Si, Ni/Ge, Ni/C, Fe/Co, Fe/Cr, Fe/Ti, Fe/W, Fe/Si, Fe/Ge, Fe/C, Co/Cr, Co/Ti, Co/W, Co/Si, Co/C, Cu/Cr, Cu/Ti, Cu/W, Cu/Si, Cu/Ge, Cu/C. The seeds layer can be prepared by screen-printing, sputtering, evaporation, vacuum arc, pulsed-laser ablation, electroplating, sol-gel, electrochemical, chemical, and chemical vapor depositions. The hydrocarbon precursor, such as acetylene, ethylene, propylene, butene, methane, ethane, propane, butane, pentane, pentanes, hexane, cyclohexane, benzene, and toluene, is used for carbon nanotubes film growth. Preferably, hydrocarbon precursor is using low bonding energy hydrocarbon precursors, such as acetylene and ethylene. The hydrocarbon precursor is diluted in hydrogen, nitrogen, argon, helium, neon, preferably in hydrogen.

By changing the concentration of the transition metal in the alloy (compound or composite), the density of the carbon nanotubes can be controlled.

Preferably, the process is carried out at low pressure (one atmospheric pressure or below), and low temperature (300-800° C.). The deposition methods include thermal CVD, plasma enhanced (microwave or radio frequency) CVD, hot-filament CVD. Preferably, thermal CVD using resistor heating or radio frequency inductive heating for low cost large area growth, plasma enhanced CVD and hot-filament CVD for low temperature (below 500° C.) growth. For carbon nanotubes film arrays, either photolithography or screen-printing process can be used for making carbon nanotube film patterns. The dielectric thin film, such as silicon oxide or silicon nitride film can be used as insulate film. The carbon nanotube film can be selectively grown in the patterned metal catalyst layer and form cathode for electron emission. The field emission devices can be made as diode or triode structures. The carbon nanotube film arrays of the present invention can be used as cathodes for flat panel display, cold cathode florescent light, and various vacuum electronic devices, such as vacuum electronic sensor, microwave amplifier, vacuum pressure gauge, electron source.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

In the drawings:

FIGS. 1(a-b) is a schematic structure of diode-type field emission of (a) vacuum-electronic device and (b) flat panel display device of the present invention.

FIGS. 2(a-b) is a schematic structure of triode-type field emission of (a) vacuum-electronic device and (b) flat panel display device of the present invention.

FIGS. 3(a-d) are cross-section schematic of fabricating a field emission cathode (diode) on a substrate of the present invention.

FIGS. 4(a-d) is a cross-section schematic of fabricating a field emission cathode (triode) on a substrate of the present invention.

FIG. 5 is a schematic of addressed field emission display of the present invention.

FIGS. 6(a-b) are the scanning electron microscopy images of patterned carbon nanotube film arrays of the present invention. (a) low magnification; (b) high magnification.

FIG. 7 is the field emission current density dependence on the applied field curve of the carbon nanotubes film of the present invention.

FIGS. 8(a-b) are the images of the spatial distribution of emission luminescent spots on the phosphor (ZnO:Zn) coated ITO-glass anode by using carbon nanotubes film of the present invention as cathode. (a) at the applied field of 5V/μm; (b) at the applied field of 8V/μm;

FIGS. 9(a-b) are the scanning electron microscopy images of patterned carbon nanotubes film arrays cathode of the present invention. (a) low magnification; (b) high magnification.

FIG. 10 an addressable diode-type field emission display device of the present invention.

### DETAILED DESCRIPTION OF THE PRESENTLY PREFERRED EMBODIMENTS

The present invention relates to process of carbon nanotubes thin film growth and field emission devices using carbon nanotubes thin film as a cathode. The carbon nanotubes having a wall comprising a single layer and multi layers of carbon atoms prepared by catalytic chemical vapor deposition using hydrocarbon precursor at low temperature. The present invention also relates to a process for making carbon nanotubes field emission devices. The process involves with some metal catalyst to effectively produce highly purified carbon nanotubes films and related devices as described below.

The process of the present invention involves hydrocarbon precursor with metal catalyst, preferably, low bonding energy hydrocarbon gases (such as acetylene, ethylene) or liquids (such as methanol, ethanol, acetone, benzene). The metal catalysts, such as Ni, Pd, Pt, Fe, Ru, Os, Co, Rh, Ir, Cu, Ag, Au, Zn, Cd, Mn, Tc, Re, Cr, Mo, W, V, Nb, Ta, Ti, Zr Hf, Sc, Y, La, and related alloys, compounds or composite films. Preferably Fe, Co, Ni, Cu, and related composite or alloys, such as Ni/Fe, Ni/Co, Ni/Cr, Ni/Ti, Ni/W, Ni/Si, Ni/Ge, Ni/C, Fe/Co, Fe/Cr, Fe/Ti, Fe/W, Fe/Si, Fe/Ge, Fe/C, Co/Cr, Co/Ti, Co/W, Co/Si, Co/C, Cu/Cr, Cu/Ti, Cu/W, Cu/Si, Cu/Ge, Cu/C. The process is carried out at low pressure (10⁻³−500 torr), and low temperature (300-800° C.), preferably in hydrogen or an inert atmosphere, such as nitrogen, argon, helium, neon. By controlling the concentration of the transit metal in the seeds layer, the density of carbon nanotubes can be tuned.

The carbon nanotubes deposition methods include thermal CVD, plasma enhanced (microwave or radio frequency) CVD, hot-filament CVD. Preferably, thermal CVD using resistor heating or radio frequency inductive heating for low cost large area growth, plasma enhanced CVD and hot-filament CVD for low temperature growth.

During the carbon nanotubes film deposition process, the ratio of hydrocarbon/hydrogen (or nitrogen, argon) is blow 50% for high purity carbon nanotubes film growth. In hydrocarbon/inert-gas mixture, a small percentage of hydrogen (below 20%) can be added in the mixture to selectively etch the amorphous carbons by plasma enhanced CVD or hot-filament CVD.

By controlling the deposition condition, the deposited carbon nanotubes or nanoparticles can be either single wall or multi walls, the deposited carbon nanotubes is hollow and the wall is cylindrically shaped. The nanoparticle is sphere shaped, the diameter is in the range of 1-500 nm, preferably less than 100 nm. The single wall of the carbon nanotube is a single carbon graphene layer. The diameter is normally less than about 5 nm. The multi wall carbon nanotube consists of many carbon graphene layers, the diameter of the tubes can be in the range of 1-500 nm, preferably less than about 100 nm. The length of the carbon nanotubes is in the range of 1 nm-10 μm, preferably more than 10 nm.

The carbon nanotubes film of the present invention can be used as field emission materials to fabricate the cathode arrays by either photolithography process or screen-printing process. The dielectric thin film, such as silicon oxide, silicon nitride, magnesium oxide, tantalum oxide or tungsten oxide film can be used as insulate film. The carbon nanotubes film can be selectively grown in the patterned metal catalyst layer and form cathode for electron emission. The field emission devices can be made as diode or triode structures. The glass, silicon, ceramic or metals can be used as cathode and anode substrates.

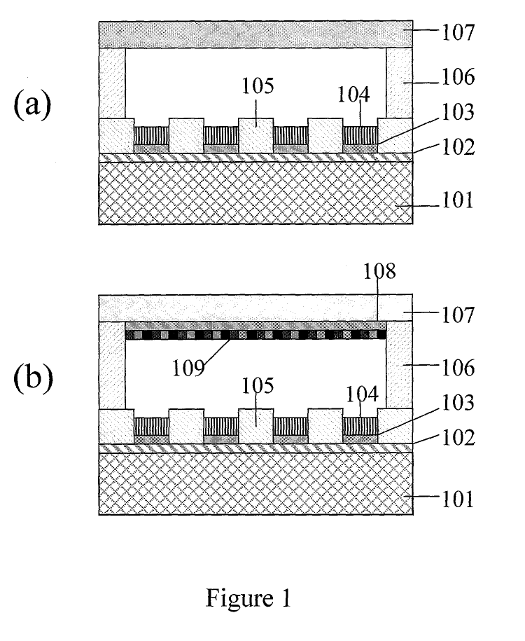

Referring to FIG. 1, the diode-type device consists of cathode, insulator spacer and anode. The cathode is a carbon nanotubes film array, including substrate (101), conductive layer (electrode) (102), catalyst layer (103), patterned CNT film (104), dielectric layer (SiO₂, Si₃N₄, MgO, TiO₂, TaO₂, W₂O₃) (105). The thickness of the dielectric layer is in the range of 1-10 μm. The conductive metal layer, such as Al, Au, Cr, Ti, W, Pt, Ag, and related alloy can be used, the thickness is in the range of 100 nm-5 μm. The thickness of the catalyst layer is in the range of 1-50 nm. The insulator spacer (106) is glass or ceramic beads, rods or walls, the thickness is in the range of 5-500 μm. For vacuum-electronic devices (FIG. 1a), the anode (107) can be metal plate, highly doped Si, or patterned conductive film arrays. For field emission display devices (FIG. 1b), the anode consists of patterned phosphor (109) coated indium tin oxide (ITO) (108)-glass substrate (107).

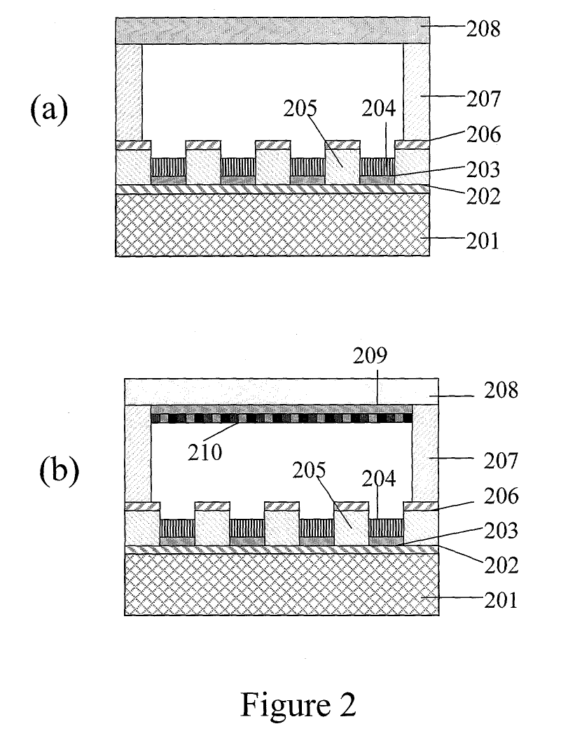

Referring to FIG. 2, the triode-type device consists of cathode, gate, insulator spacer and anode. The cathode is a carbon nanotubes film array, including substrate (201), conductive layer (electrode) (202), catalyst layer (203), patterned carbon nanotubes film (204), dielectric layer (SiO₂, Si₃N₄, MgO, TiO₂, TaO₂, W₂O₃) (205), gate metal layer (206). The thickness of the dielectric layer is in the range of 1-10 μm. The conductive metal layer, such as Al, Au, Cr, Ti, W, Pt, Ag, and related alloy can be used, the thickness is in the range of 100 nm-5 μm. The thickness of the catalyst layer is in the range of 1-50 nm. The insulator spacer (207) is a glass or ceramic beads, rods or walls, height is in the range of 5-500 μm. For vacuum-electronic devices (FIG. 2a), the anode (208) can be metal plate, highly doped Si, or patterned conductive film arrays. For field emission display devices (FIG. 2b), the anode consists of patterned phosphor (210) coated indium tin oxide (ITO) (209)-glass substrate (208).

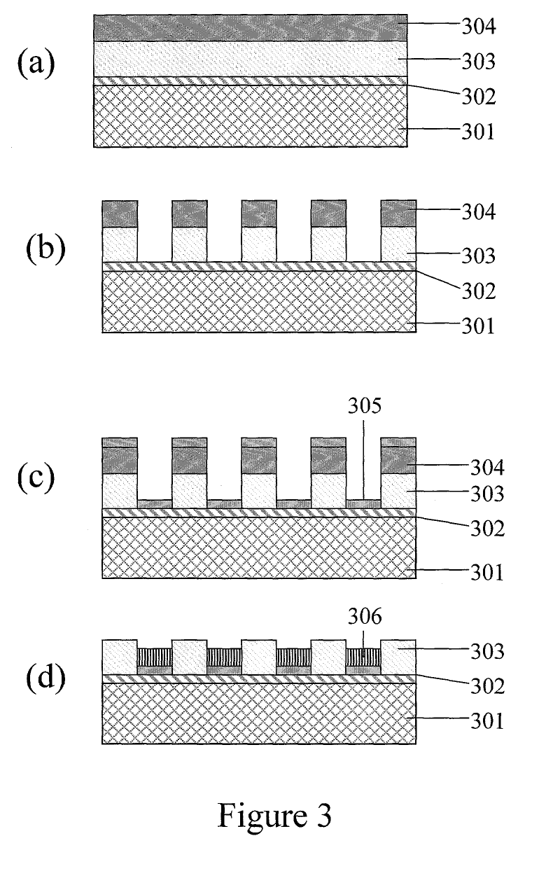

Referring to FIG. 3, the fabrication process of the carbon nanotubes cathode for diode-type device. The metal conductive layer (electrode) (302) can be deposited on the substrate (301) by using sputtering or evaporation, the dielectric layer (such as SiO₂, Si₃N₄, MgO, TiO₂, TaO₂, W₂O₃) (303) can be deposited on the metal layer by CVD or evaporation. The photo resistor layer (304) can be spinning on the dielectric layer, as shown in FIG. 3a. After photography process, the dielectric layer can be selectively etched (FIG. 3b), and then the metal catalyst seeds layer (305) can be sputtered in the trench of the substrate (FIG. 3c). Finally, get rid of the photo resistor layer (including the top metal layer) and selectively grow carbon nanotubes film arrays (306) on the seeds layer area by CVD process of present invention (FIG. 3d).

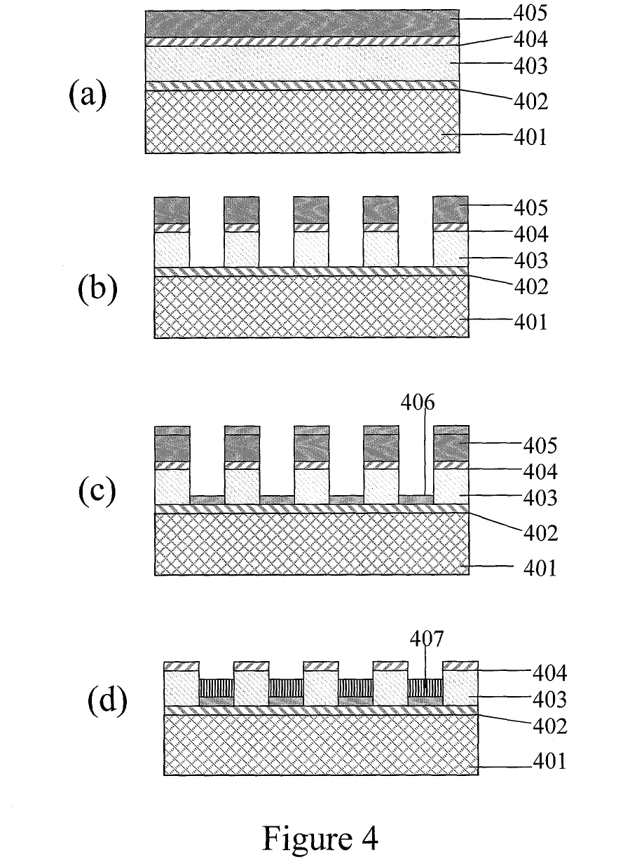

Referring to FIG. 4, the fabrication process of the carbon nanotubes cathode for triode-type device. The metal conductive layer (electrode) (402) can be deposited on the substrate (401) by using sputtering or evaporation, the dielectric layer (such as SiO₂, Si₃N₄, MgO, TiO₂, TaO₂, W₂O₃) (403) can be deposited on the metal layer by CVD or evaporation. The gate metal layer (electrode) (404) can be deposited on the dielectric layer. The photo resistor layer (405) can be spinning on the gate metal layer, as shown in FIG. 4a. After photography process, the gate metal layer and dielectric layer can be selectively etched (FIG. 4b), then the metal catalyst seeds layer (406) can be sputtered in the trench of the substrate (FIG. 4c). Finally, get rid of the photo resistor layer (including the top metal layer) and selectively grow carbon nanotubes film arrays (407) on the seeds layer area by CVD process of present invention (FIG. 4d).

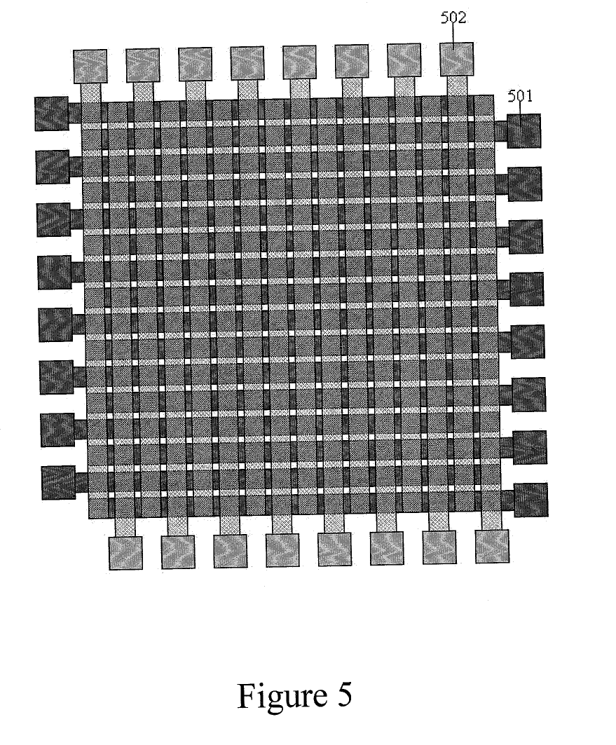

Referring to FIG. 5, a schematic of addressed field emission display of present invention. The device consists of patterned cathodes (501) as row electrodes and patterned anodes (502) as column electrodes. By controlling selected row electrodes and column electrodes, the selected regions can be displayed.

### EXAMPLE 1

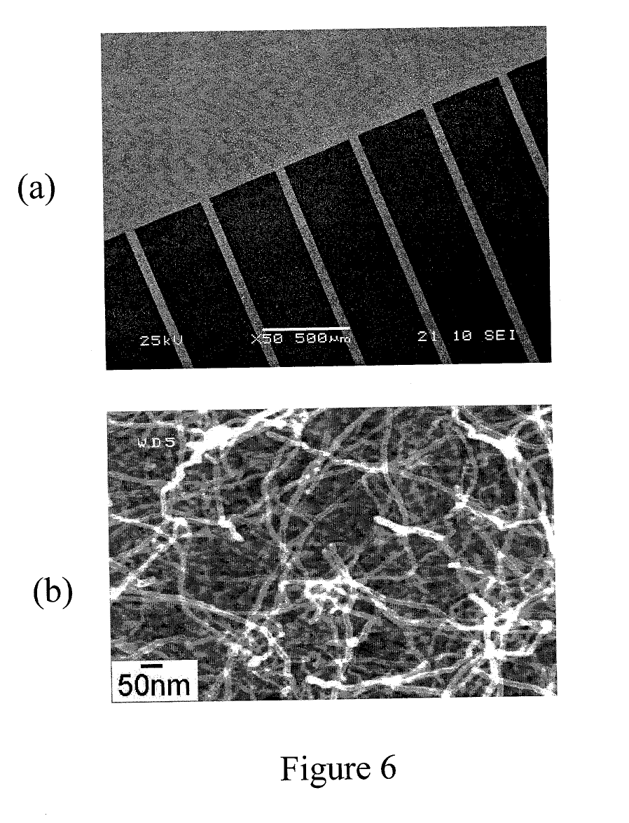

Referring to FIG. 6, the multi-wall carbon nanotubes film arrays were deposited on glass substrate by low pressure (100 torr) chemical vapor deposition using mixture of acetylene/hydrogen (2%) at 550° C. for 30 minutes. Ni/Cr (10%) alloy thin film was used as catalyst layer. The scanning electron microscopy images showing the patterned carbon nanotubes film arrays (FIG. 6a) and the morphology of carbon nanotubes (FIG. 6b) of present invention. The carbon nanotubes arrays consisted of the strips of 50 nm in width. The carbon nanotubes consisted of 10-20 nm in diameter and several hundred nm in length.

### EXAMPLE 2

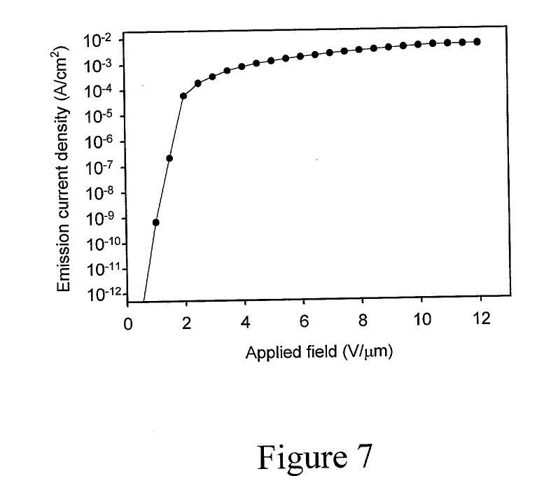

Referring to FIG. 7, the field emission current density dependence on the applied field curve of the carbon nanotubes film of present invention is shown. The field emission properties of the carbon nanotubes films were measured in a vacuum chamber at the base pressure of 10⁻⁷ Torr. The film shows an excellent emission properties, low turn-on field (below 1V/μm) and high emission current density (above 10 mA/cm² at the field of 8V/μm).

### EXAMPLE 3

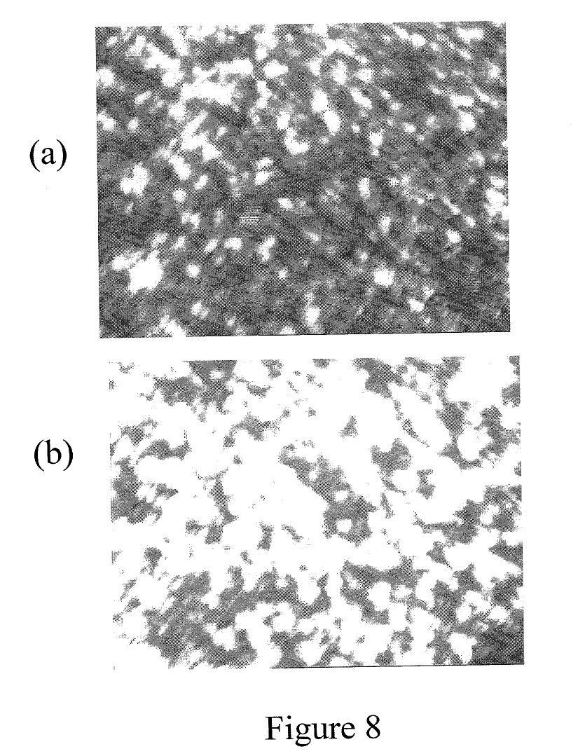

Referring to FIG. 8, the images of the spatial distribution of emission luminescent spots on phosphor (ZnO:Zn) coated ITO-glass anode by using carbon nanotubes film of the present invention as cathode can be seen. The area is 1 mm×1.2 mm. The uniform luminescent spots and high spots density (above 10⁴/cm²) can be obtained at very low field (5V/μm, FIG. 8a). With increasing the field (8V/μm, FIG. 8b), the spots density increases and the spots become bright.

### EXAMPLE 4

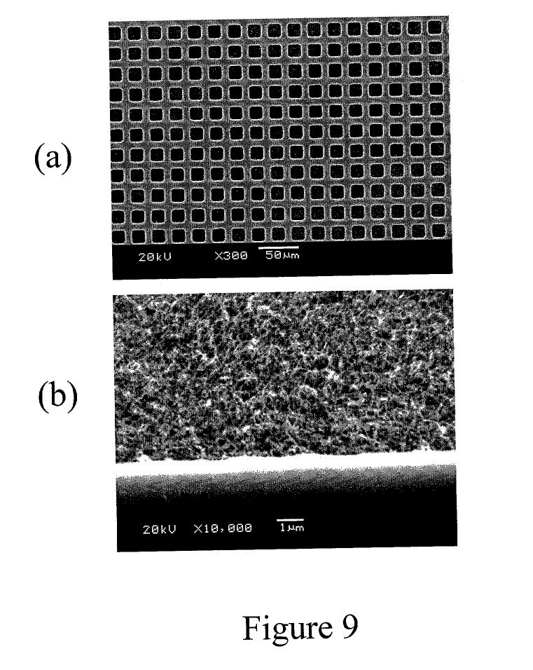

Referring to FIG. 9, the carbon nanotubes film arrays were made by photolithography process shown in FIG. 3. The carbon nanotubes film were selectively grown at the pressure of 100 torr using acetylene/hydrogen (1%) mixture at 600° C. for 30 minutes by CVD. Fe/Cr (5%) alloy thin film was used as catalyst layer. The SiO₂ layer of 1 μm in thickness was used as insulator. Each pixel area is 15 μm×15 μm, and the distance between the pixels is 10 μm (FIG. 9a). The carbon nanotubes film grown on the pixel region and isolated by SiO₂ film (FIG. 9a).

### EXAMPLE 5

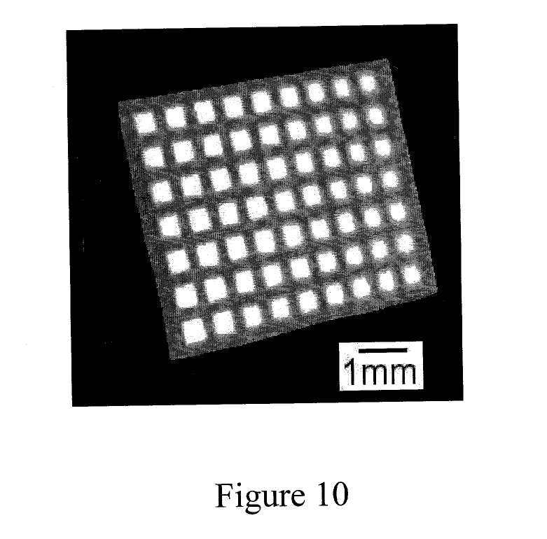

Referring to FIG. 10, an addressable diode-type field emission display device of present invention. The structure of the device is shown in FIG. 1a and FIG. 5, the fabrication process is shown in FIG. 3. The anode is patterned phosphor (ZnO:Zn) coated ITO-glass plate. The spacer between anode and cathode is 100 μm. Each pixel is 300 μm×300 μm, and the distance between the pixels is 200 μm. The uniform and bright emission patterns can be seen at the applied voltage of 800 V.

Thus, while there have shown and described and pointed out fundamental novel features of the invention as applied to a preferred embodiment thereof, it will be understood that various omissions and substitutions and changes in the form and details of the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

We claim:

1. A method for fabrication of carbon nanotubes film, comprising the steps of:
(a) Synthesizing catalyst layer consisted of at least one of the transition metals and related alloy, compound, or composite;
(b) Synthesizing carbon nanotubes film on said catalyst layer using hydrocarbon precursor by chemical vapor deposition in the pressure of 10⁻⁴ torr to 1 atm. and temperature of 300-800° C.

2. A method for fabrication of field emission cathodes, comprising the steps of:
(a) Synthesizing conductive layer on substrate;
(b) Using photolithography or screen-printing process to form patterns using dielectric materials as insulator.
(c) Selectively growth of carbon nanotubes film arrays by using method of claim 1.

3. A field emission devices comprising:
(a) A cathode consisted of a substrate, conductive layer and electron emission layer, vacuum gap and an anode;
(b) A conductive layer on the surface of said substrate;
(c) An electron emission layer consisted of carbon nanotubes on said conductive layer;

4. The method of claim 1, wherein said catalyst layer consists of at least one of the transition metals comprising Ni, Pd, Pt, Fe, Ru, Os, Co, Rh, Ir, Cu, Ag, Au, Zn, Cd, Mn, Tc, Re, Cr, Mo, W, V, Nb, Ta, Ti, Zr Hf, Sc, Y, La. Wherein said related alloy, compound, or composite which contains at least one of the transition metals, comprising Ni/Fe, Ni/Co, Ni/Cr, Ni/Ti, Ni/Mo, Ni/Al, Ni/W, Ni/Si, Ni/Ge, Ni/C, Fe/Co, Fe/Cr, Fe/Ti, Fe/Mo, Fe/Al, Fe/W, Fe/Si, Fe/Ge, Fe/C, Co/Cr, Co/Ti, Co/Mo, Co/Al, Co/W, Co/Si, Co/C, Cu/Cr, Cu/Ti, Cu/Mo, Cu/Al, Cu/W, Cu/Si, Cu/Ge, Cu/C. The thickness of the catalyst layer is below 100 μm.

5. The method of claim 1, wherein said catalyst layer is prepared by at least one method selected from the group of screen-printing, sputtering, evaporation, vacuum arc, pulsed-laser ablation, electroplating, sol-gel, electrochemical, chemical, and chemical vapor depositions.

6. The method of claim 1, wherein said carbon nanotubes have a diameter in the range of 1-500 μm, length of 1 nm-10 μm. The carbon nanotubes have a shape includes cylindrical, spherical, toroid, helical.

7. The method of claim 1, wherein said hydrocarbon precursor comprises at least one precursor selected from the group of acetylene, ethylene, propylene, butene, methane, ethane, propane, butane, pentane, pentanes, hexane, cyclohexane, benzene, and toluene. The hydrocarbon precursor is diluted comprises at least one gas selected from the group of hydrogen, nitrogen, argon, helium, neon.

8. The method of claim 1, wherein said chemical vapor deposition comprises thermal chemical vapor deposition, plasma enhanced (microwave or radio frequency) chemical vapor deposition, hot-filament chemical vapor deposition.

9. The method of claim 2, wherein said conductive layer comprises at least one material selected from the group consisting of Cr, Al, Au, Ag, Cr, Ti, Cu, Ni, Fe, Co, Pt, Mo, W, ZnO, InO, ITO (indium-tin oxide).

10. The method of claim 2, wherein said dielectric materials comprise silicon oxide, silicon nitride, magnesium oxide, tantalum oxide, titanium oxide and tungsten oxide films.

11. The methods of claim 2, wherein said substrate comprises at least one material selected from the group consisting of glass, semiconductor, metal, alloy, ceramic, composite materials.

12. The method of claim 3, wherein said anode comprises at least a conductive substrate or a conductive layer said in claim 9 on substrate said of claim 11. For display devices, the anode comprises phosphor, transparent conductive layer and glass substrate.

13. A method of controlling shape, diameter and length and density of the carbon nanotubes in the film by selecting the transition metal said in claim 4 and concentration of the transition metal in the alloys, compounds, or composites.

14. A flat panel display devices comprising the field emission device of claim 1.

15. Vacuum electronic devices comprising microwave amplifier, vacuum-electronic sensor, vacuum pressure gauge, spectrometer, electron microscopy, electron beam source, by using the field emission device of claim 1.

16. A cold cathode light source comprising using the field emission device of claim 1.
